(19) United States
(12) Patent Application Publication
(10) Pub. No.: US 2026/0140214 A1
(43) Pub. Date: May 21, 2026

(54) COARSE SLICE RESOLUTION UPSAMPLING FOR TWO-DIMENSIONAL MAGNETIC RESONANCE IMAGING

(71) Applicant: Siemens Medical Solutions USA, Inc., Malvern, PA (US)

(72) Inventors: Joshua Schaefferkoetter, Knoxville, TN (US); Jorge Cabello, Lenoir City, TN (US)

(21) Appl. No.: 18/953,547

(22) Filed: Nov. 20, 2024

(51) Int. Cl. G01R 33/56; G01R 33/561

(52) U.S. Cl. CPC G01R 33/5608; G01R 33/5611

(57) ABSTRACT

For coarse-slice resolution upsampling, a machine-learned model or network infers data or samples along or between slices (e.g., creates extra slices) from the 2D MRI data (e.g., from the stack of slices). Rapid scanning may be used to create the stack of slices with poor slice-to-slice resolution, and a 3D volume with better resolution across slices is provided by inference from the stack of slices.

### FIELD

This disclosure relates to magnetic resonance (MR) imaging (MRI).

### BACKGROUND

For clinical MRI, high resolution images are desired. It is not generally practical to run 3D sequences due to the length of time during which the patient is required to hold their breath or not move and/or the time to scan while gating to a physiological cycle. For this reason, high resolution images are acquired in two dimensions with fine in-plane resolution. A two-dimensional (2D) volume of a stack of slices with fine in-plane resolution but coarse slice-to-slice spacing may be acquired more rapidly. Poor resolution is provided along one dimension of the volume of the patient where high resolution along all dimensions is generally desired. Interpolation of new slices to increase the resolution across the slices may not produce satisfactory results.

### SUMMARY

By way of introduction, the preferred embodiments described below include methods, systems, instructions, and non-transitory computer readable media for coarse-slice resolution upsampling. A machine-learned model or network infers data or samples along or between slices (e.g., creates extra slices) from the 2D MRI data (e.g., from the stack of slices). Rapid scanning may be used to create the stack of slices with poor slice-to-slice resolution, and a 3D volume with better resolution across slices is provided by inference from the stack of slices.

In a first aspect, a method is provided for coarse-slice resolution upsampling for magnetic resonance imaging. A magnetic resonance system scans a patient. The scan uses a two-dimensional (2D) imaging protocol providing samples in a stack of slices with greater resolution within each slice than between the slices. A machine-learned network upsamples between the slices. The machine-learned network outputs additional slices for the upsampling. A magnetic resonance image is generated from the stack of slices and the additional slices.

In a second aspect, a method is provided for coarse-slice resolution upsampling for magnetic resonance imaging. A two-dimensional (2D) magnetic resonance volume is input to a deep convolutional network. A three-dimensional (3D) magnetic resonance volume is formed from the 2D magnetic resonance volume and output of the deep convolutional network. A magnetic resonance image is generated from the 3D magnetic resonance volume.

In a third aspect, a system is provided for increasing resolution in magnetic resonance imaging. A magnetic resonance scanner is configured to scan a patient. An image processor is configured to reconstruct a volumetric stack of two-dimensional (2D) magnetic resonance slices from data from the scan and to infer, by a machine-learned model, a three-dimensional (3D) magnetic resonance volume from the volumetric stack. The 3D magnetic resonance volume has a greater resolution along the slices than the volumetric stack. A display is configured to display an image of the patient generated from the 3D magnetic resonance volume.

Any one or more of the aspects or concepts summarized above or in the Illustrative Examples below may be used alone or in combination. The aspects or concepts described for one Illustrative Example or aspect may be used in other embodiments or aspects. The aspects or concepts described for a method or system may be used in others of a system, method, or non-transitory computer readable storage medium.

The present invention is defined by the following claims, and nothing in this section should be taken as a limitation on those claims. The illustrative examples below summarize further aspects. Further aspects and advantages of the invention are discussed below in conjunction with the preferred embodiments and may be later claimed independently or in combination.

### BRIEF DESCRIPTION OF THE DRAWINGS

FIG. 1 is a flow chart diagram of one example of a method for coarse-slice resolution upsampling in MRI;

FIG. 2 illustrates an example 2D MR volume;

FIG. 3 illustrates an example machine-learned model for increasing resolution across slices;

FIG. 4 shows example MR images;

FIG. 5 is a block diagram of an example of an MR system for medical imaging with a machine-trained model;

FIG. 6 illustrates an example neural network for upsampling; and

FIG. 7 illustrates an example convolutional network for upsampling.

### DETAILED DESCRIPTION

Coarse-slice resolution upsampling is provided for 2D MR imaging. A machine-learned model, such as a deep convolutional network, is used to generate a high-resolution MR image in 3D from a corresponding coarse stack for 2D slices. The fine in-plane resolution is used in inference to optimize the upsampling across planes or slices. The machine-learned model leverages the in-plane, high-resolution information, already present (in 2D) within the 3D volume(s), to infer a finer slice spacing.

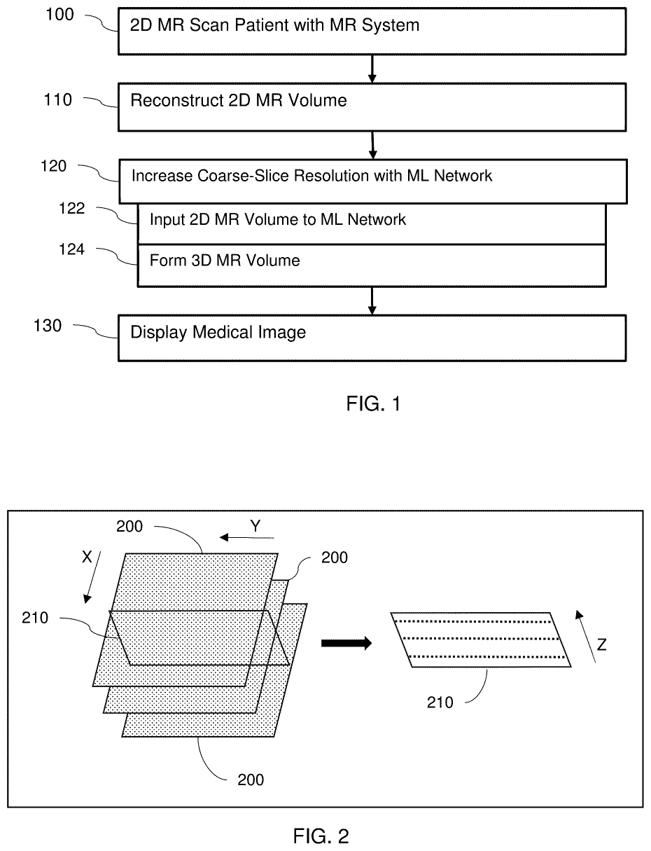

FIG. 1 is a flow chart diagram of one embodiment of a method for coarse-slice resolution upsampling for MR imaging. A machine-learned model is applied to upsample across slices of a 2D MRI volume. The speed of 2D MR imaging is provided, but the MR image may be generated from higher resolution information across slices, similar to 3D MR imaging.

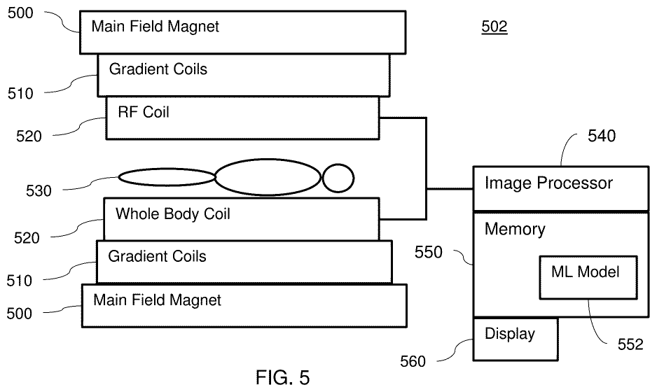

The method is performed by the system of FIG. 5 or another system. The MR system scans the patient. An image processor reconstructs and increases coarse-slice resolution in the reconstructed volume. A display displays the MR image generated from the MR volume. Other components may be used, such as a remote server or a workstation performing the reconstruction, upsampling, and/or display.

The method is performed in the order shown (top-to-bottom or numerical) or other orders. Additional, different, or fewer acts may be provided. For example, a preset, default, or user input settings are used to configure the scanning prior art act 100. As another example, the image is stored in a memory (e.g., computerized patient medical record) or transmitted over a computer network instead of or in addition to the display of act 130. In another example, acts 100 and/or 110 are not provided, such as where an already reconstructed 2D MR volume is acquired from memory.

In act 100, the MR system scans a patient. The scanning results in measurements. A pulse sequence is created based on the configuration of the MR system (e.g., the imaging protocol selected). The pulse sequence is transmitted from coils into the patient. The resulting responses are measured by receiving radio frequency signals at the same or different coils. The scanning results in k-space measurements as the scan data.

The scan is guided by a protocol. The scan may fully sample a volume. A 3D sequence to fully and/or evenly sample throughout a volume is performed. 3D MR imaging may be time consuming, such as 3-5 minutes per bed position. Gating to a physiological cycle and/or redoing due to failure of a patient to hold their breath may cause the 3D MR scan to take even longer.

Sparse sampling may be performed. For 2D MR volume imaging, a plurality of slices is scanned. For each slice, full or high resolution is provided, such as 1 mm or less per sample location. The slices are not spaced at that resolution. The slices may be 2-10 mm or more apart. For example, the slices are parallel but 6-8 mm apart. The 2D imaging protocol provides a stack of slices with greater resolution within each slice than between the slices.

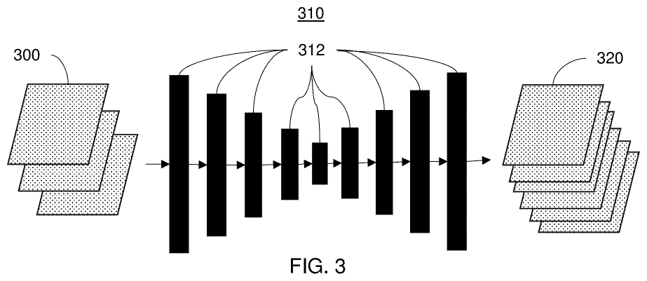

FIG. 2 shows an example with three slices 200. This representation is after reconstruction in act 110. While three slices 200 are shown, four or more (e.g., tens or hundreds) of slices may be stacked. In the X and Y dimensions (in slice dimensions) of this example, a relatively higher resolution is provided (e.g., 0.9 mm). In the Z dimension (across or between slices), less resolution (e.g., 5 mm or greater) is provided for the 2D MR volume. For example, a plane 210 extending along one dimension in the slice (e.g., Y dimension) and the Z dimension has relatively higher resolution along the Y dimension and relatively poor (e.g., 6 mm) across the slices (along Z dimension).

Any of various 2D MR imaging protocols may be used. For example, spin echo, T1, T2, or other protocol using slice sampling is performed. In one approach, a half-Fourier Single-shot Turbo spin-Echo (HASTE) protocol is performed. Using HASTE, the patient volume may be scanned in about 20 seconds (about accounts for 10% deviation) per bed position. Other protocols may be used. By scanning less than 20 seconds, 30 seconds, 1 minute, or 2 minutes per bed position, more clinically useful scanning is provided, with a resulting downside of less resolution across slices. When a 3D scan protocol is not practical or possible, the 2D MR scan protocol may be used.

In act 110, an image processor reconstructs a representation of the patient from the k-space scan data. The image processor reconstructs an MR volume, such as a 2D MR volume as the stack of slices 200 of FIG. 2. For MR reconstruction, the k-space data is transformed into an image or object representation, such as scalar values representing different spatial locations. Pixel or voxel values are reconstructed as the MR volume. The spatial distribution of measurements in object or image space is formed. This spatial distribution is an image representing the patient.

The reconstruction may use optimization, such as SENSE, GRAPPA, or iterative reconstruction algorithms. In another approach, the reconstruction uses a machine learning model. The k-space data is input to the machine learning model, and the machine learning model outputs the volume representation (e.g., stack of slices)

Other processing may be performed on the input k-space measurements before reconstruction. Other processing may be performed on the output representation or reconstruction, such as spatial filtering, color mapping, and/or display formatting.

In act 120, an image processor upsamples between or along the slices. Additional slices are created for between existing slices of the stack. A 3D volume is formed from the stack of 2D slices. Any increase in resolution across slices may be provided, such as adding slices to cause the slice dimension Z to have a resolution similar (e.g., +/−10%) to the in-plane or in-slice resolution (e.g., about 1.0 or 0.9 mm). In another approach, the increase is provided by resampling so that an evenly sampled 3D volume (e.g., 0.9 mm or 1.0 mm per voxel) in all three dimensions is provided. Any increase in resolution, such as doubling the resolution along the Z or slice dimension, is provided. The resolution in the slice (e.g., X and Y dimensions) may stay the same, be increased, or decrease.

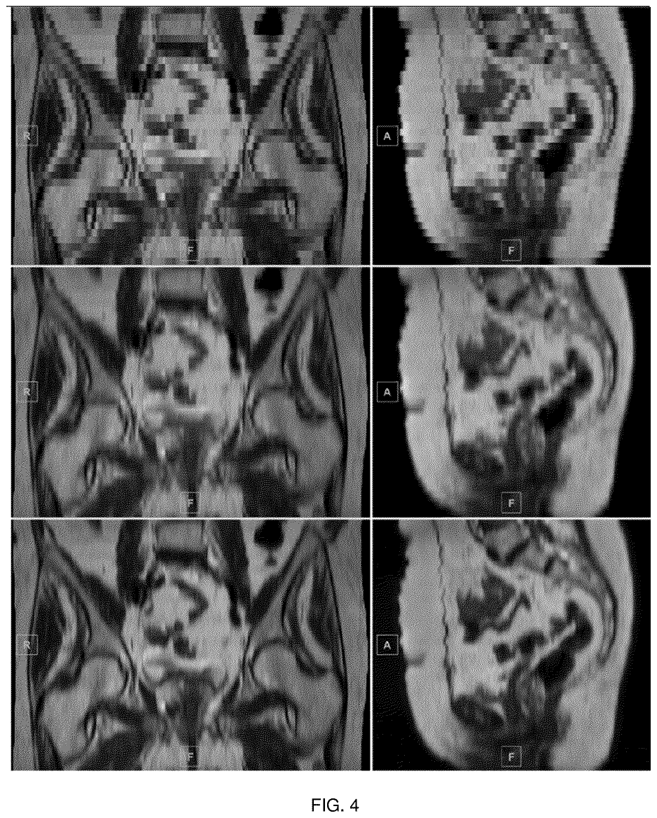

A machine-learned model, such as a machine-learned network, upsamples or increases the resolution. The machine-learned model outputs additional slices or voxels for slices for increasing the resolution across slices. FIG. 3 shows an example. The machine-learned network 310 receives the stack 300 of slices (see FIG. 2) and outputs a 3D volume 320 with greater resolution along the Z dimension (across the slices). In the example of FIG. 3, the machine-learned model doubles the resolution across the slices, such as by forming an extra slice for each slice of the input stack 300 or by forming a 3D volume with a resolution double the resolution along the Z dimension of the input stack 300. Other increases in resolution, such as by 5 or 6 times, may be provided.

Any machine-learned model may be used. Any architecture or layer structure for machine learning may be used, such as a convolutional neural network. The architecture defines the structure, learnable parameters, and relationships between parameters. In one embodiment, a convolutional, transformer-based, or another neural network is used. Any number of layers and nodes within layers may be used. A DenseNet, U-Net, encoder-decoder, Deep Iterative Down-Up convolutional neural network (CNN), image-to-image, and/or another network may be used. Part of the network may include dense blocks (i.e., multiple layers in sequence outputting to the next layer as well as the final layer in the dense block). Down sampling and/or up sampling layers may be included. Skip connections may be used. Any known or later developed neural network or other deep learning network may be used. Any number of hidden layers and/or nodes may be provided between the input layer and output layer.

FIG. 3 shows an example of the neural network 310. The neural network 310 is a cascade of different convolutional, pooling, and up-sampling layers 312. An input layer receives the slices of the stack 300 or 2D MR volume. The network structure forms an encoder with increasing abstraction from an initial layer 312 and a decoder with decreasing abstraction to a final layer 312. The layers 312 may include convolution layers. The convolution layers have respective convolution kernels, where each kernel is formed from learnable parameters. An output layer outputs the additional slices and/or 3D MR volume 320. Additional, different, or fewer layers may be used. Other types of layers may be used as well or instead.

Machine training, such as deep learning, is used to train the architecture as defined. The model is trained to receive inputs (stack 300) and generate outputs (stack 320) in response. The values for the learnable parameters (e.g., kernels) of the architecture are learned.

Training data is used to train the model. The training data is acquired from memory, scanning, or transfer. To machine train, training data is created, gathered, or accessed.

The training data includes many sets of data, such as 2D MR volumes (stacks 300) and respective outputs (additional slices and/or 3D MR volumes). For example, full 3D volume scans are performed on many patients. The resulting reconstructed 3D MR volumes are gathered as ground truths. The 3D MR volumes may be down sampled or sampled to simulate 2D MR scanning, providing a stack or stacks 300 for each ground truth 3D MR volume 320 to be output. Tens, hundreds, or thousands of training sample are acquired, such as from scans of patients, scans of phantoms, simulation of scanning, and/or by image processing to create further samples. In one approach, patient data from a hospital(s), imaging facility(ies), or patient health records are used.

To train, the training data stacks 300 are input to the network 310. The network 310 generated output is compared to the ground truth. The values for the learnable parameters that result in the least loss (most similar outputs) from the ground truths given the variety of inputs of the training data are learned. A computer (e.g., image processor, workstation, or server) or another machine trains the model (e.g., network 310) for inferring the additional slices and/or 3D MR volume 320 from an input stack 300 of 2D MR. The neural network 310 is machine trained. In one embodiment, deep learning is used to train the model. The training learns both the features of the input data and the conversion of those features to the desired output. Backpropagation, RMSprop, ADAM, or another optimization is used in learning the values of the learnable parameters of the network (e.g., the convolutional neural network (CNN) or fully connection network (FCN)). The difference from the output (e.g., inferred 3D MR volume 320) to the ground truth is minimized. Any measure of difference may be used, such as a sum of mean-squared-error (MSE) or mean-absolute-error (MAE). L1, L2, or other loss may be used.

Once trained, the architecture with the learned values is applied. The image processor inputs the stack 300 reconstructed from a scan of the patient to the machine-learned model, which outputs the 3D MR volume 320, such as formatted as additional slices or a full 3D MR volume. In other approaches, the machine-learned model may be trained to receive k-space data and output the reconstructed 3D MR volume 320.

During application of the machine-learned model to one or more different patients and corresponding different scan data, the same learned weights or values are used. The model and values for the learnable parameters are not changed from one patient to the next, at least over a given time (e.g., weeks, months, or years) or given number of uses (e.g., tens or hundreds). These fixed values and corresponding fixed model are applied sequentially and/or by different processors for different patients. The model may be updated, such as retrained, or replaced but does not learn new values as part of application for a given patient.

Acts 122 and 124 represent an example implementation for increasing the coarse-slice resolution with a machine-learned network or other model. Additional, different, or fewer acts may be provided for upsampling across the slices.

In act 122, the image processor inputs a 2D MR volume to a deep convolutional network 310. The slices 200 of the stack 300 are input to the input channels of the machine-learned network. Slices (images or samples in planes or areas) with a first resolution in the slices that is finer than the resolution across the slices are input.

The machine-learned network outputs in response to the input. The input data propagates into the network 310, where the values of the learned parameters and the architecture control calculation of values of features. The output is generated by inference. Finer slice spacing or higher resolution along the slice dimension is inferred in response to the input.

Additional inputs may be provided. For example, clinical information about the patient is also input. The machine-learned network was trained to use the additional input as well as the 2D MR volume. As another example, the patient is scanned from different orientations. Multiple 2D MR volumes with the slice dimension oriented differently relative to the patient are input to generate an output. Alternatively, each 2D MR volume is input separately, and the resulting 3D MR volumes are combined.

In act 124, the image processor forms the 3D MR volume from the 2D magnetic resonance volume and output of the deep convolutional network 310. The network 310 infers finer slice spacing than the slice spacing of the input. The resolution along at least one dimension is made higher by inference. The fine in-plane resolution of the slices is used in inference to optimize the upsampling across planes or slices. The machine-learned model leverages the in-plane, high-resolution information, already present (in 2D) within the 3D volume(s), to infer a finer slice spacing.

In one approach, the network 310 infers or outputs additional slices in response to input. The image processor then adds the additional slices to the stack 300 of the 2D MR volume to create the 3D MR volume. The inferred intervening slices are combined with the original slices. In another approach, the additional slices are inferred as part of a 3D MR volume. The network 310 outputs a 3D MR volume. The full 3D MR volume is output. The slices of the 3D MR volume may or may not include the input slices 200 of the input stack 300 (of the 2D MR volume). The 3D MR volume is directly inferred by the network.

The same deep machine-learned model (e.g., network 310) may be used for different patients. The same or different copies of the same machine-learned model are applied for different patients, resulting in patient-specific representations or reconstructions using the same values or weights of the learned parameters of the model. Different patients and/or the same patient at a different time may be scanned while the same or fixed trained machine-learned model is used. Other copies of the same deep machine-learned model may be used for other patients.

In act 130, the image processor and/or another processor (e.g., graphics processing unit) generates a MR image from the output (e.g., from the stack 320 of slices and the additional slices). The MR image is generated form the 3D MR volume. A display (e.g., display screen or device) displays the MR image. The MR image, after or as part of any post processing, is formatted for display on the display. The display generates the image for viewing by the user, radiologist, physician, clinician, and/or patient. The image assists in diagnosis and/or another clinical purpose.

The displayed image may represent a planar region or area in the patient. The area may have any orientation relative to the 3D MR volume and patient. Where the orientation extends along, at least partly, the stack (i.e., across slices), the increased resolution across or between the slices results in increased resolution in the MR image. One dimension of the area for the MR image may be across slices of the 2D MR volume. Due to the increased resolution or upsampling between slices, a greater resolution is provided for the MR image. Pixels in the MR image along one dimension are from slices and additional slices inferred by the machine-learned model.

FIG. 4 shows examples. HASTE MR imaging is used on a test subject. The slices are trans axial (transverse plane), so the slices are perpendicular to the longitudinal axis of the patient. The left column shows the same image along a coronal plane (coronal view perpendicular to the transverse view). The right column shows the same image along a sagittal plane (sagittal view perpendicular to the transverse view). For both the coronal and sagittal views, the Y axis is across the slices. The top row shows MR images created from the 2D MR volume without upsampling by the machine-learned model. The middle row shows MR images generated with a simple linear interpolation between slices to a finer resolution. The bottom row shows MR images at the finer resolution but based on output of the 3D MR volume of the machine-learned model. Both the MR images of the middle and bottom rows have the same higher resolution than the top row, but the MR images generated from the 3D MR volume created by the machine-learned model appear more realistic (sharper or less blurry) than the MR images created by simple interpolation.

In an alternative, or additional, approach, the displayed image is a volume or surface rendering from voxels (three-dimensional distribution) to the two-dimensional display. The 3D MR volume is used to render, such as a 3D rendering from a perspective. The higher resolution of the 3D MR volume may result in better 3D renderings.

FIG. 5 shows one embodiment of a system for increasing resolution in MR imaging. A high-quality 3D surrogate is generated by the machine-learned model 552 from a volumetric stack of 2D MRI slices. The system scans or acquires a reconstruction of a given patient and applies the machine-learned model 552 to upsample.

The system is implemented by an MR scanner 502 or system, a computer, a server, or another processor. The MR scanner 502 is only exemplary, and a variety of MR scanning systems can be used to collect the MR data. In the embodiment of FIG. 5, the system is or includes the MR scanner 502 or MR system. The MR scanner 502 is configured to scan a patient. The scan acquires a 2D MR volume (volumetric representation of the patient along coarsely spaced slices or planes). The scan provides scan data in a scan domain. The system scans a patient to provide k-space measurements (measurements in the frequency domain).

In the MR medical scanner 502, a main magnetic coil 500 creates a static base magnetic field (B0) in the body of patient 530. Gradient coils 510, in response to gradient signals supplied thereto by a gradient and shim coil control module, produce position dependent and shimmed magnetic field gradients in three orthogonal directions and generate magnetic field pulse sequences.

RF coil 520 (whole body and/or local coils), which in response to RF pulse signals, produces magnetic field pulses that rotate the spins of the protons in the imaged body of the patient 530. Gradient and shim coil control module in conjunction with RF module, as directed by central controller, control slice-selection, phase-encoding, readout gradient magnetic fields, radio frequency transmission, and magnetic resonance signal detection, to acquire magnetic resonance signals representing planar slices of the patient 530.

In response to applied RF pulse signals, the RF coil 520 receives MR signals. The MR signals are detected and processed to provide an MR dataset to an image processor 540 for processing into an image (i.e., for reconstruction in the object domain from the k-space data in the scan domain). In some implementations, the image processor 540 is in or is the central controller, control processor, or control system.

The MR scanner 502 is configured to scan the patient 530 in less than 30 seconds per bed position. Rather than scanning for a full 3D MR volume with the same or similar resolution along all three dimensions, the scan is made more rapid by scanning more sparsely. Multiple slices or planes are scanned with coarser resolution between the slices and finer resolution within the slices. Longer duration scans may be used.

The image processor 540 is an image processor that reconstructs a representation of the patient from the k-space data, upsamples (increases resolution across slices), and/or renders an MR image. The image processor 540 is a general processor, digital signal processor, three-dimensional data processor, graphics processing unit, application specific integrated circuit, field programmable gate array, artificial intelligence processor, tensor processor, digital circuit, analog circuit, combinations thereof, and/or another now known or later developed device for upsampling with the machine-learned model 552. The image processor 540 is a single device, a plurality of devices, or a network. For more than one device, parallel or sequential division of processing may be used. Different devices making up the image processor 540 may perform different functions, such as reconstructing by one device, upsampling by another device, and rendering by yet another device. In one embodiment, the image processor 540 is a control processor or another processor of the MR scanner 502. Other image processors of the MR scanner 502 or external to the MR scanner 502 may be used.

The image processor 540 is configured by software, firmware, and/or hardware to apply the machine-learned model 552 to increase resolution between slices. The image processor 540 operates pursuant to instructions stored on a non-transitory medium (e.g., memory 550) to perform various acts described herein.

The image processor 540 is configured to reconstruct a representation in an object domain. The reconstruction is a 2D MR volume or a stack of slices with greater resolution in the slices than between the slices. The image processor 540 is configured to reconstruct a volumetric stack of 2D MR slices from data from the scan (k-space data).

The image processor 540 is configured to implement the machine-learned model 552, such as the convolutional neural network 310 of FIG. 3 or another model. The image processor 540 is configured to infer, by application of the machine-learned model 552, a 3D MR volume from the 2D MR volumetric stack. Based on the inference by the machine-learned model 552, the 3D MR volume has a greater resolution along, across, or between the slices than the reconstructed volumetric stack input to the machine-learned model 552. The machine-learned model 552 infers additional slices, either as slices to be added to the stack or as slices forming an output 3D MR volume. The additional slices are added to the volumetric stack to form the 3D MR volume.

The machine-learned model 552, such as trained as discussed above, is applied as discussed above for FIG. 1 by the image processor 540. The machine-learned model 552 may be the network of FIG. 3 or another architecture. For example, the machine-learned model 552 is a deep convolutional network formed as an encoder-decoder, U-Net, or another image-to-image network (input spatial samples to output spatial samples).

The image processor 540 is configured to generate an image of the patient. The image is generated from the 3D MR volume. Due to the increased (higher or better) resolution between the slices, the image may better represent the patient without requiring a longer scan.

The display 560 is a CRT, LCD, plasma, projector, printer, or other display device. The display 560 is configured by loading an image to a display plane or buffer. The display 560 is configured to display the image of the patient generated from the 3D MR volume. The image has a dimension along slices with a same or similar (+/−10%) resolution as within the slices. The image of the patient is displayed to assist in diagnosis.

The memory 550 stores scan data, the machine-learned model 552, the 2D MR volume, the 3D MR volume, the MR image, and/or other data. The memory 550 is additionally or alternatively a non-transitory computer readable storage medium with processing instructions. The memory 550 stores data representing instructions executable by the programmed processor 540, such as instructions for upsampling.

The instructions for implementing the processes, methods and/or techniques discussed herein are provided on non-transitory computer-readable storage media or memories, such as a cache, buffer, RAM, removable media, hard drive, or other computer readable storage media. Computer readable storage media include various types of volatile and nonvolatile storage media. The functions, acts or tasks illustrated in the figures or described herein are executed in response to one or more sets of instructions stored in or on computer readable storage media. The functions, acts or tasks are independent of the particular type of instructions set, storage media, processor or processing strategy and may be performed by software, hardware, integrated circuits, firmware, micro code and the like, operating alone or in combination. Likewise, processing strategies may include multiprocessing, multitasking, parallel processing and the like. In one embodiment, the instructions are stored on a removable media device for reading by local or remote systems. In other embodiments, the instructions are stored in a remote location for transfer through a computer network or over telephone lines. In yet other embodiments, the instructions are stored within a given computer, CPU, GPU, or system.

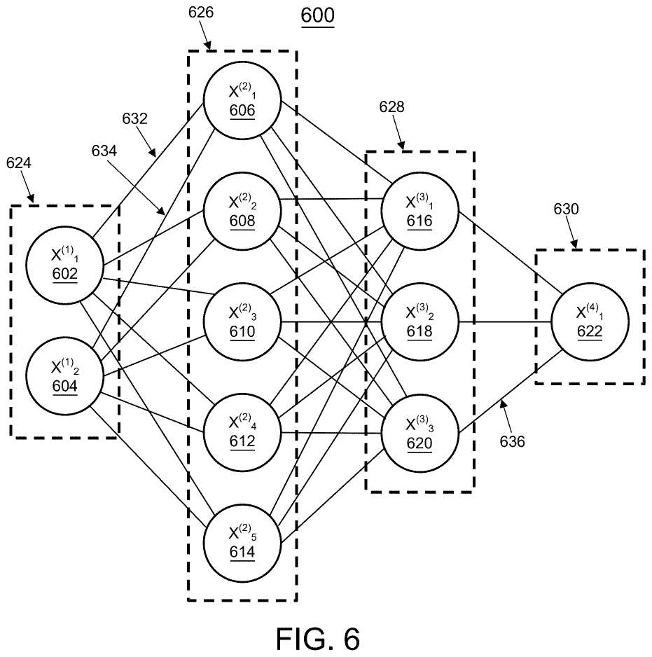

FIG. 6 shows an embodiment of an artificial neural network 600, in accordance with one or more embodiments (e.g., network 310 or machine-learned model 552). Alternative terms for “artificial neural network” are “neural network,” “artificial neural net” or “neural net.” Machine learning networks described herein, such as, e.g., the one or more machine learning based networks utilized at step 120 of FIG. 1, the network 310 of FIG. 3, the machine-learned model 552 of FIG. 5, or any other machine learning network described herein may be implemented using artificial neural network 600.

The artificial neural network 600 comprises nodes 602-622 and edges 632, 634, . . . , 636, wherein each edge 632, 634, . . . , 636 is a directed connection from a first node 602-622 to a second node 602-622. In general, the first node 602-622 and the second node 602-622 are different nodes 602-622, it is also possible that the first node 602-622 and the second node 602-622 are identical. For example, in FIG. 6, the edge 632 is a directed connection from the node 602 to the node 606, and the edge 634 is a directed connection from the node 604 to the node 606. An edge 632, 634, . . . , 636 from a first node 602-622 to a second node 602-622 is also denoted as “ingoing edge” for the second node 602-622 and as “outgoing edge” for the first node 602-622.

In this implementation, the nodes 602-622 of the artificial neural network 600 can be arranged in layers 624-630, wherein the layers can include an intrinsic order introduced by the edges 632, 634, . . . , 636 between the nodes 602-622. In particular, the edges 632, 634, . . . , 636 can exist only between neighboring layers of nodes. In the implementation shown in FIG. 6, there is an input layer 624 comprising only nodes 602 and 604 without an incoming edge, an output layer 630 comprising only node 622 without outgoing edges, and hidden layers 626, 628 in-between the input layer 624 and the output layer 630. In general, the number of hidden layers 626, 628 can be chosen arbitrarily. The number of nodes 602 and 604 within the input layer 624 usually relates to the number of input values of the neural network 600, and the number of nodes 622 within the output layer 630 usually relates to the number of output values of the neural network 600.

In particular, a (real) number can be assigned as a value to every node 602-622 of the neural network 600. Here, x⁽ⁿ⁾ᵢ denotes the value of the i-th node 602-622 of the n-th layer 624-630. The values of the nodes 602-622 of the input layer 624 are equivalent to the input values of the neural network 600, the value of the node 622 of the output layer 630 is equivalent to the output value of the neural network 600. Furthermore, each edge 632, 634, . . . , 636 can include a weight being a real number, in particular, the weight is a real number within the interval [−1, 1] or within the interval [0, 1]. Here, w^{(m,n)}_{i,j} denotes the weight of the edge between the i-th node 602-622 of the m-th layer 624-630 and the j-th node 602-622 of the n-th layer 624-630. Furthermore, the abbreviation w⁽ⁿ⁾_{i,j} is defined for the weight w^{(n,n+1)}_{i,j}.

In particular, to calculate the output values of the neural network 600, the input values are propagated through the neural network. In particular, the values of the nodes 602-622 of the (n+1)-th layer 624-630 can be calculated based on the values of the nodes 602-622 of the n-th layer 624-630 by

$${x}_{j}^{( n + 1 )} = f ( {\sum }_{i} {x}_{i}^{( n )} \cdot {w}_{i , j}^{( n )} ) .$$

Herein, the function f is a transfer function (another term is “activation function”). Known transfer functions are step functions, sigmoid function (e.g., the logistic function, the generalized logistic function, the hyperbolic tangent, the Arctangent function, the error function, the smoothstep function) or rectifier functions. The transfer function is mainly used for normalization purposes.

In particular, the values are propagated layer-wise through the neural network, wherein values of the input layer 624 are given by the input of the neural network 600, wherein values of the first hidden layer 626 can be calculated based on the values of the input layer 624 of the neural network, wherein values of the second hidden layer 628 can be calculated based in the values of the first hidden layer 626, etc.

To set the values w^{(m,n)}_{i,j} for the edges, the neural network 600 has to be trained using training data. In particular, training data comprises training input data and training output data (denoted as tᵢ). For training, the neural network 600 is applied to the training input data to generate calculated output data. In particular, the training data and the calculated output data comprise a number of values, said number being equal with the number of nodes of the output layer.

In particular, a comparison between the calculated output data and the training data is used to recursively adapt the weights within the neural network 600 (backpropagation algorithm). In particular, the weights are changed according to:

$${w}_{i , j}^{′ ( n )} = {w}_{i , j}^{( n )} - γ \cdot {δ}_{j}^{( n )} \cdot {x}_{i}^{( n )}$$

wherein γ is a learning rate, and the numbers δ⁽ⁿ⁾ⱼ can be recursively calculated as:

$${δ}_{j}^{( n )} = ( {\sum }_{k} {δ}_{k}^{( n + 1 )} \cdot {w}_{j , k}^{( n + 1 )} ) \cdot {f}^{′} ( {\sum }_{i} {x}_{i}^{( n )} \cdot {w}_{i , j}^{( n )} )$$

based on δ⁽ⁿ⁺¹⁾ⱼ, if the (n+1)-th layer is not the output layer, and

$${δ}_{j}^{( n )} = ( {x}_{k}^{( n + 1 )} - {t}_{j}^{( n + 1 )} ) \cdot {f}^{′} ( {\sum }_{i} {x}_{i}^{( n )} \cdot {w}_{imj}^{( n )} )$$

if the (n+1)-th layer is the output layer 630, wherein f′ is the first derivative of the activation function, and y⁽ⁿ⁺¹⁾ⱼ is the comparison training value for the j-th node of the output layer 630.

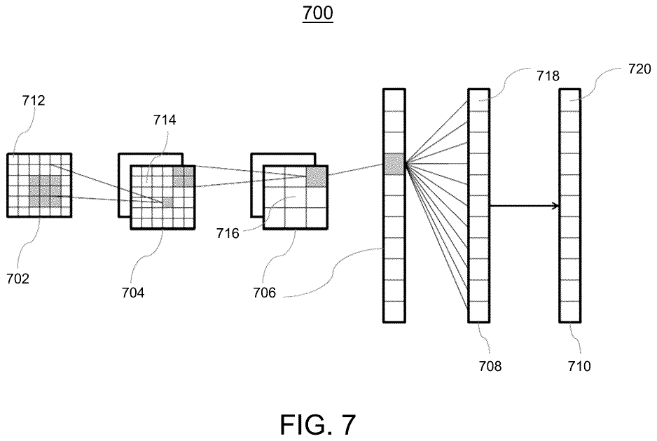

FIG. 7 shows a convolutional neural network 700, in accordance with one or more embodiments. Machine learning networks described herein, such as, e.g., the machine learning based network utilized at step 120 of FIG. 1, the network 310 of FIG. 3, the machine-learned model 552 of FIG. 5, or any other machine learning network described herein may be implemented using the convolutional neural network 700.

In the implementation shown in FIG. 7, the convolutional neural network comprises 700 an input layer 702, a convolutional layer 704, a pooling layer 706, a fully connected layer 708, and an output layer 710. Alternatively, the convolutional neural network 700 can include several convolutional layers 704, several pooling layers 706, and several fully connected layers 708, as well as other types of layers. The order of the layers can be chosen arbitrarily, usually fully connected layers 708 are used as the last layers before the output layer 710.

In particular, within a convolutional neural network 700, the nodes 712-720 of one layer 702-710 can be considered to be arranged as a d-dimensional matrix or as a d-dimensional image. In particular, in the two-dimensional case, the value of the node 712-720 indexed with i and j in the n-th layer 702-710 can be denoted as x⁽ⁿ⁾_{[i,j]}. However, the arrangement of the nodes 712-720 of one layer 702-710 does not have an effect on the calculations executed within the convolutional neural network 700 as such, since these are given solely by the structure and the weights of the edges.

In particular, a convolutional layer 704 is characterized by the structure and the weights of the incoming edges forming a convolution operation based on a certain number of kernels. In particular, the structure and the weights of the incoming edges are chosen such that the values x⁽ⁿ⁾ₖ of the nodes 714 of the convolutional layer 704 are calculated as a convolution x⁽ⁿ⁾ₖ=Kₖ*x⁽ⁿ⁻¹⁾ based on the values x⁽ⁿ⁻¹⁾ of the nodes 712 of the preceding layer 702, where the convolution * is defined in the two-dimensional case as

$${x}_{k}^{( n )} [ i , j ] = ( {K}_{k} * {x}^{( n - 1 )} ) [ i , j ] = {\sum }_{{i}^{′}} {\sum }_{{j}^{′}} {K}_{k} [ {i}^{′} , {j}^{′} ] \cdot {x}^{( n - 1 )} [ i - {i}^{′} , j - {j}^{′} ] .$$

Here the k-th kernel Kₖ is a d-dimensional matrix (in this embodiment a two-dimensional matrix), which is usually small compared to the number of nodes 712-718 (e.g., a 3×3 matrix, or a 5×5 matrix). In particular, this implies that the weights of the incoming edges are not independent but chosen such that they produce said convolution equation. In particular, for a kernel being a 3×3 matrix, there are only 9 independent weights (each entry of the kernel matrix corresponding to one independent weight), irrespectively of the number of nodes 712-720 in the respective layer 702-710. In particular, for a convolutional layer 704, the number of nodes 714 in the convolutional layer is equivalent to the number of nodes 712 in the preceding layer 702 multiplied with the number of kernels.

If the nodes 712 of the preceding layer 702 are arranged as a d-dimensional matrix, using a plurality of kernels can be interpreted as adding a further dimension (denoted as “depth” dimension), so that the nodes 714 of the convolutional layer 704 are arranged as a (d+1)-dimensional matrix. If the nodes 712 of the preceding layer 702 are already arranged as a (d+1)-dimensional matrix comprising a depth dimension, using a plurality of kernels can be interpreted as expanding along the depth dimension, so that the nodes 714 of the convolutional layer 704 are arranged also as a (d+1)-dimensional matrix, wherein the size of the (d+1)-dimensional matrix with respect to the depth dimension is by a factor of the number of kernels larger than in the preceding layer 702.

The advantage of using convolutional layers 704 is that spatially local correlation of the input data can be exploited by enforcing a local connectivity pattern between nodes of adjacent layers, in particular by each node being connected to only a small region of the nodes of the preceding layer.

In embodiment shown in FIG. 7, the input layer 702 includes 36 nodes 712, arranged as a two-dimensional 6×6 matrix. The convolutional layer 704 includes 72 nodes 714, arranged as two two-dimensional 6×6 matrices, each of the two matrices being the result of a convolution of the values of the input layer with a kernel. Equivalently, the nodes 714 of the convolutional layer 704 can be interpreted as a three-dimensional 6×6×2 matrix, wherein the last dimension is the depth dimension.

A pooling layer 706 can be characterized by the structure and the weights of the incoming edges and the activation function of its nodes 716 forming a pooling operation based on a non-linear pooling function f. For example, in the two-dimensional case, the values x⁽ⁿ⁾ of the nodes 716 of the pooling layer 706 can be calculated based on the values x⁽ⁿ⁻¹⁾ of the nodes 714 of the preceding layer 704 as

$${x}^{( n )} [ i , j ] = f ( {x}^{( n - 1 )} [ i {d}_{1} , {jd}_{2} ] , … , {x}^{( n - 1 )} [ i {d}_{1} + {d}_{1} - 1 , {jd}_{2} + {d}_{2} - 1 ] )$$

In other words, by using a pooling layer 706, the number of nodes 714, 716 can be reduced, by replacing a number d1·d2 of neighboring nodes 714 in the preceding layer 704 with a single node 716 being calculated as a function of the values of said number of neighboring nodes in the pooling layer. In particular, the pooling function f can be the max-function, the average, or the L2-Norm. In particular, for a pooling layer 706 the weights of the incoming edges are fixed and are not modified by training.

The advantage of using a pooling layer 706 is that the number of nodes 714, 716 and the number of parameters is reduced. This leads to the amount of computation in the network being reduced and to a control of overfitting.

In the embodiment shown in FIG. 7, the pooling layer 706 is a max-pooling, replacing four neighboring nodes with only one node, the value being the maximum of the values of the four neighboring nodes. The max-pooling is applied to each d-dimensional matrix of the previous layer; in this embodiment, the max-pooling is applied to each of the two two-dimensional matrices, reducing the number of nodes from 72 to 18.

A fully-connected layer 708 can be characterized by the fact that a majority, in particular, all edges between nodes 716 of the previous layer 706 and the nodes 718 of the fully-connected layer 708 are present, and wherein the weight of each of the edges can be adjusted individually.

In this implementation, the nodes 716 of the preceding layer 706 of the fully-connected layer 708 are displayed both as two-dimensional matrices, and additionally as non-related nodes (indicated as a line of nodes, wherein the number of nodes was reduced for a better presentability). In this implementation, the number of nodes 718 in the fully connected layer 708 is equal to the number of nodes 716 in the preceding layer 706. Alternatively, the number of nodes 716, 718 can differ.

Furthermore, in this implementation, the values of the nodes 720 of the output layer 710 are determined by applying the Softmax function onto the values of the nodes 718 of the preceding layer 708. By applying the Softmax function, the sum of the values of all nodes 720 of the output layer 710 is 1, and all values of all nodes 720 of the output layer are real numbers between 0 and 1.

A convolutional neural network 700 can also comprise a ReLU (rectified linear units) layer or activation layers with non-linear transfer functions. In particular, the number of nodes and the structure of the nodes contained in a ReLU layer is equivalent to the number of nodes and the structure of the nodes contained in the preceding layer. In particular, the value of each node in the ReLU layer is calculated by applying a rectifying function to the value of the corresponding node of the preceding layer.

The input and output of different convolutional neural network blocks can be wired using summation (residual/dense neural networks), element-wise multiplication (attention) or other differentiable operators. Therefore, the convolutional neural network architecture can be nested rather than being sequential if the whole pipeline is differentiable.

In particular, convolutional neural networks 700 can be trained based on the backpropagation algorithm. For preventing overfitting, methods of regularization can be used, e.g., dropout of nodes 712-720, stochastic pooling, use of artificial data, weight decay based on the L1 or the L2 norm, or max norm constraints. Different loss functions can be combined for training the same neural network to reflect the joint training objectives. A subset of the neural network parameters can be excluded from optimization to retain the weights pretrained on another datasets.

Below are various illustrative Examples. The Illustrative Examples summarize different combinations of aspects. Different combinations of approaches or aspects may be used. Example method acts may be provided in systems and vice versa. Examples used in application may be used in training.

Illustrative Example 1. A method for coarse-slice resolution upsampling for magnetic resonance imaging, the method comprising: scanning, by a magnetic resonance system, a patient, the scanning using a two-dimensional (2D) imaging protocol providing samples in a stack of slices with greater resolution within each slice than between the slices; upsampling, by a machine-learned network, between the slices, the machine-learned network outputting additional slices for the upsampling; and generating a magnetic resonance image from the stack of slices and the additional slices.

Illustrative Example 2. The method of Illustrative Example 1, wherein scanning comprises scanning with the 2D imaging protocol comprising a half-Fourier Single-shot Turbo spin-Echo (HASTE) protocol.

Illustrative Example 3. The method of any of Illustrative Examples 1-2, wherein scanning comprises scanning for less than 30 seconds per bed position.

Illustrative Example 4. The method of any of Illustrative Examples 1-3, wherein scanning comprises scanning with an in-slice resolution at or less than 1 mm per pixel after reconstruction and a slice-by-slice resolution 5 mm or greater between slices.

Illustrative Example 5. The method of Illustrative Example 4, wherein upsampling comprises upsampling such that the additional slices between the slices of the stack provide for the slice-by-slice resolution at or less than 1 mm between the slices and additional slices.

Illustrative Example 6. The method of Illustrative Example 5, wherein generating the magnetic resonance image comprise generating the magnetic resonance image having a dimension along the stack of slices and the additional slices.

Illustrative Example 7. The method of any of Illustrative Examples 1-6, wherein upsampling comprises upsampling by the machine-learned network comprising a convolutional neural network.

Illustrative Example 8. The method of any of Illustrative Examples 1-7, wherein upsampling comprises inputting the slices of the stack into the machine-learned network, the machine-learned network outputting the additional slices in response to the inputting.

Illustrative Example 9. The method of any of Illustrative Examples 1-8, wherein upsampling comprises forming a three-dimensional magnetic resonance volume from the stack of slices.

Illustrative Example 10. The method of any of Illustrative Examples 1-9, wherein generating the magnetic resonance image comprises generating a 2D image representing an area of the patient wherein pixels of the 2D image along one dimension are from the slices and additional slices.

Illustrative Example 11. A method for coarse-slice resolution upsampling for magnetic resonance imaging, the method comprising: inputting a two-dimensional (2D) magnetic resonance volume to a deep convolutional network; forming a three-dimensional (3D) magnetic resonance volume from the 2D magnetic resonance volume and output of the deep convolutional network; and generating a magnetic resonance image from the 3D magnetic resonance volume.

Illustrative Example 12. The method of Illustrative Example 11, wherein the 2D magnetic resonance volume comprises slices with a first resolution in the slices, the first resolution being finer than a second resolution across the slices, and wherein inputting comprises inferring finer slice spacing by the deep convolutional network than the second resolution based on information in slices with the first resolution.

Illustrative Example 13. The method of any of Illustrative Examples 11-12, wherein forming comprises outputting the 3D magnetic resonance volume by the deep convolutional network in response to the inputting.

Illustrative Example 14. The method of any of Illustrative Examples 11-13, wherein forming comprises combining the information as additional slices output by the deep convolutional network in response to the inputting with the 2D magnetic resonance volume.

Illustrative Example 15. The method of any of Illustrative Examples 11-14, wherein generating comprises generating the magnetic resonance image comprising a 2D magnetic resonance image representing an area, one dimension of the area being across slices of the 2D magnetic resonance volume.

Illustrative Example 16. A system for increasing resolution in magnetic resonance imaging, the system comprising: a magnetic resonance scanner configured to scan a patient; an image processor configured to reconstruct a volumetric stack of two-dimensional (2D) magnetic resonance slices from data from the scan, to infer by a machine-learned model a three-dimensional (3D) magnetic resonance volume from the volumetric stack, the 3D magnetic resonance volume having a greater resolution along the slices than the volumetric stack; and a display configured to display an image of the patient generated from the 3D magnetic resonance volume.

Illustrative Example 17. The system of Illustrative Example 16, wherein the image processor is configured to infer the 3D magnetic resonance volume by inferring additional slices, the image processor configured to insert the additional slices into the volumetric stack to form the 3D magnetic resonance volume.

Illustrative Example 18. The system of any of Illustrative Examples 16-17, wherein the machine-learned model comprises a deep convolutional network.

Illustrative Example 19. The system of any of Illustrative Examples 16-18, wherein the magnetic resonance scanner is configured to scan in less than 30 seconds per bed position.

Illustrative Example 20. The system of any of Illustrative Examples 16-19, wherein the image has a dimension along slices with a same resolution as a dimension within one of the slices.

Although the subject matter has been described in terms of exemplary embodiments, it is not limited thereto. Rather, the appended claims should be construed broadly, to include other variants and embodiments, which can be made by those skilled in the art.

What is claimed is:

1. A method for coarse-slice resolution upsampling for magnetic resonance imaging, the method comprising:
scanning, by a magnetic resonance system, a patient, the scanning using a two-dimensional (2D) imaging protocol providing samples in a stack of slices with greater resolution within each slice than between the slices;
upsampling, by a machine-learned network, between the slices, the machine-learned network outputting additional slices for the upsampling; and
generating a magnetic resonance image from the stack of slices and the additional slices.

2. The method of claim 1, wherein scanning comprises scanning with the 2D imaging protocol comprising a half-Fourier Single-shot Turbo spin-Echo (HASTE) protocol.

3. The method of claim 1, wherein scanning comprises scanning for less than 30 seconds per bed position.

4. The method of claim 1, wherein scanning comprises scanning with an in-slice resolution at or less than 1 mm per pixel after reconstruction and a slice-by-slice resolution 5 mm or greater between slices.

5. The method of claim 4, wherein upsampling comprises upsampling such that the additional slices between the slices of the stack provide for the slice-by-slice resolution at or less than 1 mm between the slices and additional slices.

6. The method of claim 5, wherein generating the magnetic resonance image comprise generating the magnetic resonance image having a dimension along the stack of slices and the additional slices.

7. The method of claim 1, wherein upsampling comprises upsampling by the machine-learned network comprising a convolutional neural network.

8. The method of claim 1, wherein upsampling comprises inputting the slices of the stack into the machine-learned network, the machine-learned network outputting the additional slices in response to the inputting.

9. The method of claim 1, wherein upsampling comprises forming a three-dimensional magnetic resonance volume from the stack of slices.

10. The method of claim 1, wherein generating the magnetic resonance image comprises generating a 2D image representing an area of the patient wherein pixels of the 2D image along one dimension are from the slices and additional slices.

11. A method for coarse-slice resolution upsampling for magnetic resonance imaging, the method comprising:
inputting a two-dimensional (2D) magnetic resonance volume to a deep convolutional network;
forming a three-dimensional (3D) magnetic resonance volume from the 2D magnetic resonance volume and output of the deep convolutional network; and
generating a magnetic resonance image from the 3D magnetic resonance volume.

12. The method of claim 11, wherein the 2D magnetic resonance volume comprises slices with a first resolution in the slices, the first resolution being finer than a second resolution across the slices, and wherein inputting comprises inferring finer slice spacing by the deep convolutional network than the second resolution based on information in slices with the first resolution.

13. The method of claim 11, wherein forming comprises outputting the 3D magnetic resonance volume by the deep convolutional network in response to the inputting.

14. The method of claim 11, wherein forming comprises combining the information as additional slices output by the deep convolutional network in response to the inputting with the 2D magnetic resonance volume.

15. The method of claim 11, wherein generating comprises generating the magnetic resonance image comprising a 2D magnetic resonance image representing an area, one dimension of the area being across slices of the 2D magnetic resonance volume.

16. A system for increasing resolution in magnetic resonance imaging, the system comprising:
a magnetic resonance scanner configured to scan a patient;
an image processor configured to reconstruct a volumetric stack of two-dimensional (2D) magnetic resonance slices from data from the scan, to infer by a machine-learned model a three-dimensional (3D) magnetic resonance volume from the volumetric stack, the 3D magnetic resonance volume having a greater resolution along the slices than the volumetric stack; and
a display configured to display an image of the patient generated from the 3D magnetic resonance volume.

17. The system of claim 16, wherein the image processor is configured to infer the 3D magnetic resonance volume by inferring additional slices, the image processor configured to insert the additional slices into the volumetric stack to form the 3D magnetic resonance volume.

18. The system of claim 16, wherein the machine-learned model comprises a deep convolutional network.

19. The system of claim 16, wherein the magnetic resonance scanner is configured to scan in less than 30 seconds per bed position.

20. The system of claim 16, wherein the image has a dimension along slices with a same resolution as a dimension within one of the slices.
